(19) United States
(12) Patent Application Publication
(10) Pub. No.: US 2013/0017317 A1
(43) Pub. Date: Jan. 17, 2013

(54) LOAD LOCK CONTROL METHOD AND APPARATUS

(71) Applicants: Kenneth M. Ring, Waterville, OH (US); Rick C. Powell, Ann Arbor, MI (US); William Logan, Perrysburg, OH (US); Feng Liao, Perrysburg, OH (US); Xilin Peng, Bloomington, MN (US)

(72) Inventors: Kenneth M. Ring, Waterville, OH (US); Rick C. Powell, Ann Arbor, MI (US); William Logan, Perrysburg, OH (US); Feng Liao, Perrysburg, OH (US); Xilin Peng, Bloomington, MN (US)

(21) Appl. No.: 13/549,118

(22) Filed: Jul. 13, 2012

Related U.S. Application Data
(60) Provisional application No. 61/507,161, filed on Jul. 13, 2011.

(51) Int. Cl. C23C 16/52

(52) U.S. Cl. 427/8; 118/712

(57) ABSTRACT

Method and apparatus for controlling evacuation pressure of a load lock connected to a processing chamber uses prior pressure changes detected in the processing chamber when the load lock communicates with the processing chamber.

### CROSS-REFERENCE TO RELATED APPLICATION

This application claims priority to U.S. Provisional Application No. 61/507,161, filed on Jul. 13, 2011, the entirety of which is incorporated by reference.

### SCOPE OF THE INVENTION

Embodiments disclosed herein relate to a method and apparatus for controlling entry or exit load locks to a main processing chamber.

Processing chambers which have one or more entry and exit load locks for repeatedly loading an object to be processed into the chamber, or discharging a processed object from the chamber, are known in the art. In the field of photovoltaic module fabrication such processing chambers in the form of vapor transport deposition coaters (VTD) can be used in an assembly line where they operate at moderate vacuum (1-10 Torr) with very fast cycle times. Typically, because of the processing requirements for the module substrate, such coaters employ a single-stage exit vacuum load lock, which places stringent restrictions on exit times from the VTD coater and the operation of an exit load lock. The entry load lock is typically also constructed as a single stage load lock which is often vented with air to receive a module for processing. The purpose of the entry load lock is to establish within the load lock a vacuum pressure which is very close to that of the VTD coater chamber such that processing pressures within the coater chamber are not disturbed as an object to be processed is passed from the entry load lock into the coater chamber. Likewise, an exit load lock also has its pressure substantially equalized to that of the coater chamber before a module which has been processed by the coater chamber is passed to the exit load lock and from there to subsequent stages of processing.

For an entry load lock, its cycle time is partitioned between in transport, where an object is loaded within the entry load lock through a flap valve, evacuation, where the atmosphere within the load lock is evacuated to a lower pressure, pressure matching of the load lock to the coater chamber, out transport of the object from the entry to the coater chamber through another flap valve, valve operation, and venting of the entry load lock back to the ambient pressure to allow feeding of a next module substrate into the entry load lock.

The cycle time of an exit load lock is partitioned between evacuation of the exit load lock to lower its pressure, valve operation, pressure matching of the pressure within the exit load lock to that of the coater chamber, transport of an object from the coater chamber to the exit load lock through a flap valve, venting of the exit load lock to a pressure associated with discharge, and finally discharge of the object from the exit load lock through another flap valve.

In both the entry and exist load locks, the allocated time for pressure matching between the load lock and the coater chamber is severely restricted due to short cycle times, finite transfer speeds, and limited pumping speeds.

One technique which has been used for matching the pressure within the entry or exit load lock to that of the VTD coater chamber is by using a differential pressure gauge which measures pressure in the coater chamber and in the relevant load lock. Differential pressure measurements between the load lock and coater chamber trigger the closing of the evacuation valves in the load locks once a manually set threshold is reached and thus the set minimum load lock pressure is reached in a cycle. Any significant pressure mismatch between the load lock and the coater chamber results in a net gas flow between them when a flap valve, which separates the coater chamber from a load lock, is opened. The flow between the load lock and coater chamber can be significant and can impact the processing which is performed within the coater chamber.

For fast cycle times associated with high throughput very high pumping speeds are required in the load locks for evacuation. Further, the manually adjusted evacuation valve close thresholds must be properly set periodically by the operator to compensate for finite valve actuation times. In addition to requiring periodic observation of all pressure gauges by an operator for setting the evacuation valve closing thresholds, the response times of the differential pressure gauges change over time as protection filters for the gauges accumulate debris. Thus, in order to maintain a consistent transient flow at each flap valve open event, which allows communication of an entry or exit load lock with the coater chamber, a continual manual adjustment of the pressure thresholds at which the actuation valve thresholds are set and a close monitoring of the differential pressure gauge filters are also required.

A more reliable method and apparatus for determining the valve close thresholds for the evacuation valves in an entry and an exit load lock is therefore desirable.

### BRIEF DESCRIPTION OF THE DRAWINGS

FIG. 1 illustrates in schematic form a main processing chamber including associated entry and exit load locks and the various gauges, valves and pumps associated therewith;

FIG. 2 illustrates the overall control system for controlling the evacuation level thresholds of the entry and exit load locks illustrated in FIG. 1;

FIG. 3 illustrates an example of a control algorithm executed by the programmable logic controller illustrated in FIG. 2 for controlling evacuation level thresholds of the entry and exit load locks; and

FIG. 4 illustrates an example of a leak detection system which may be incorporated into the programmable logic controller illustrated in FIG. 2.

### DETAILED DESCRIPTION OF THE INVENTION

The embodiments described herein provide a method and apparatus to automatically control the evacuation pressure within entry and exit load locks so that a consistent cycle-to-cycle low transient gas flow between the load locks and a main processing chamber is maintained. This is accomplished by using a transient signal of a main chamber pressure gauge to detect the actual pressure pulse when the flap valves interconnecting the main chamber with a respective load lock are opened and closed. By measuring the main chamber pressure just before and just after flap valve operation, a pressure change (ΔP) is obtained which can be used as the input to a control system for the adjustment of the evacuation valve close threshold pressure for future cycles of a respective load lock. In this way a particular ΔP can be targeted so, for example, one can set the system such that a net consistent small gas flow between the main chamber and load lock is maintained where the load locks communicate with the main chamber. Since the main processing chamber for a VTD coater can be constructed as a relatively large vessel, the pressure changes are relatively small but are easily measurable.

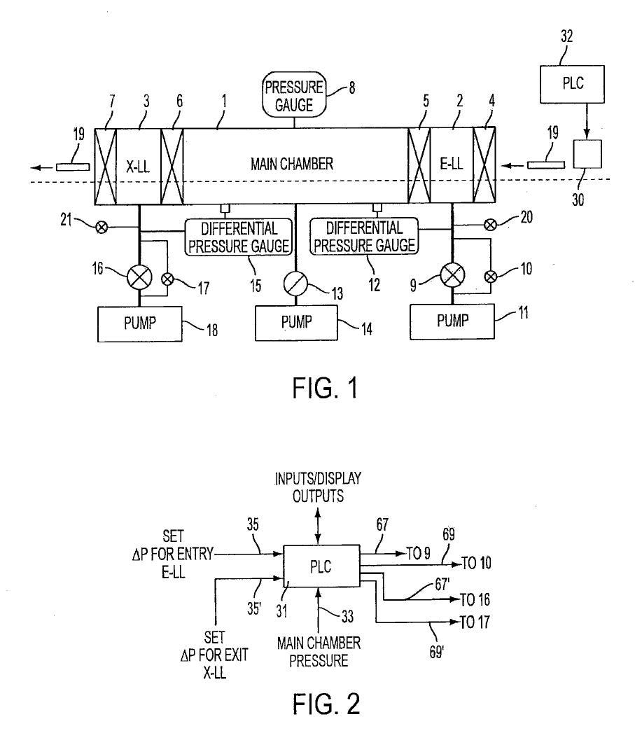

FIG. 1 illustrates the example of a processing system with which embodiments of the invention may be used. As an example of the processing which may be performed by the main processing chamber, the vapor deposition coating of glass substrates for use in fabricating solar modules is described herein. However, it should be understood that this is just one example of a processing environment with which the embodiment described herein can be used and that the embodiment described herein can be used with any processing chamber having an entry or exit load lock.

As shown in FIG. 1, a glass substrate 19 is conveyed by a conveying system 30 through entry load lock 2, into main VTD processing chamber 1, and from there to an exit load lock 3, from which it exits the overall processing system illustrated. The entry load lock 2 has two flap valves 4 and 5, one (4) on the entry side and one (5) on the exit side of entry load lock 2. Flap valve 4, when opened, communicates the entry load lock 2 with an upstream location while flap valve 5 communicates the entry load lock 2 with the main processing chamber 1 when opened. Likewise, the exit load lock 3 has two flap valves 6 and 7 with flap valve 6 communicating the exit load lock 3 with the main processing chamber 1, and with flap valve 7 communicating the exit load lock 3 with a downstream processing apparatus.

Main processing chamber 1 includes a pressure gauge 8. In one example, the main chamber pressure gauge can be a capacitive manometer gauge having a range of 0-10 Torr, and having a high sensitivity of approximately 0.0001 Torr and better than 0.12% accuracy. The conveyance of a substrate 19 to be processed through the entry load lock 2, main chamber 1, and exit load lock 3, by the conveying system 30 as well as timing control of the flap valves 4, 5, 6 and 7, are under control of a conveying system programmable logic controller 32. As noted, the main processing chamber 1 can be a VTD coater, operating under moderate vacuum deposition conditions of 1-10 Torr.

In order to control the evacuation of the entry load lock 2, a pump 11 is provided which quickly evacuates load lock 2 through two valves 9 and 10. Valve 9 is a larger evacuation valve having a larger flow rate than smaller evacuation valve 10, which is a smaller and more precise evacuation valve and with a smaller flow rate than that of evacuation valve 9. On the exiting side, the exit load lock 3 is similarly arranged. A pump 18 provided on the exit side evacuates the exiting load lock 3 through a larger valve 16 having a larger flow rate than valve 17, which is a smaller and more precise valve having a smaller flow rare than valve 16.

A vent valve 20 is provided in association with the entry load lock to vent the load lock chamber to atmosphere or with another gas such as N2 prior to the opening of flap valve 4, while a like vent valve 21 is provided in association with the exit load lock 3 to vent the load lock chamber with pressurized N2 prior to flap valve 7 opening. A main chamber pump 14 and associated throttle valve 13 are used to maintain a desired processing pressure within the main chamber 1.

Embodiments described herein control the evacuation of the entry 2 and exit 3 load lock chambers by setting the closing pressure thresholds for the valves 9 and 10 for the entry load lock 2 and closing pressure thresholds for valves 6 and 17 for the exit load lock 3. The closing pressure thresholds cause the valves to close when a desired differential pressure is reached between the respective entry and exit load locks 2 and 3 and the main chamber 1. An automatic control system is provided for setting those evacuation pressure thresholds in accordance with detected pressure differences sensed by the main chamber pressure gauge 8 in response to one or more prior opening and closing operations of the load locks.

FIG. 2 shows in block diagram form a control system for setting the closing threshold pressures for the large and small evacuation valves 9, 10 of the entry load lock 2 and the large and small evacuation valves 16, 17 of the exit load lock 3. As shown a programmable logic controller 31 receives at an input 35 a desired differential pressure ΔP which should be experienced in the main processing chamber 1 at the opening and closing of flap valve 5. The controller 31 also receives on input 35′ a desired differential pressure ΔP which should be experienced in the main processing chamber 1 when flap valve 6 for the exit load lock 3 opens and closes. The programmable logic controller 31 may be separate from or part of the programmable logic controller 32 for the conveying mechanism 30. Accordingly, the control system may include one or more programmable logic controllers 31 and 32 performing the control functions of each as described herein. Controller 31 sets the closing evacuation pressure thresholds which results in altered activation times of the large and small evacuation valves 9, 10 of the entry load lock. Controller 31 also sets closing evacuation pressure thresholds for the large and small evacuation valve 16, 17 of the exit load lock. Controller 31 also receives an input 33 which is the pressure within the main chamber 1 as sensed by pressure gauge 8 for one or more prior openings and closings of flap valves and uses this and the set point inputs 35, 35′ to set, by way of control signals on lines 67, 69, 67′ and 69′, the evacuation pressure closing thresholds for valves 9, 10 and 16, 17. Programmable logic controller 31 also can receive other inputs and set and display outputs, as will be described in greater detail below.

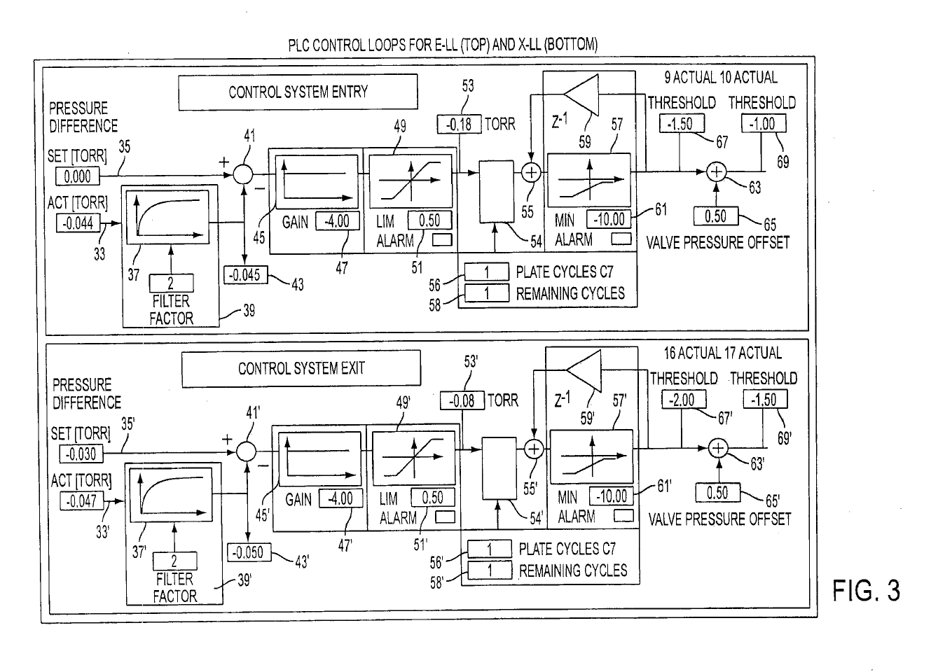

FIG. 3 illustrates the logic control systems within the programmable logic controller 31 which are used to implement and set the evacuation pressure closing thresholds for the large and small evacuation valves 9 and 10 for entry load lock 2 and for the large and small evacuation valves 16 and 17 for exit load lock 3. The logic control system for the entry load lock is shown in the upper portion of FIG. 3 and that for the exit load lock is shown on the bottom portion of FIG. 3.

Since the control for each of the entry and exit load locks 2 and 3 function virtually identically, and have the same logical construction, a detailed description will only be provided for the logic control system for entry load lock 2, which is illustrated in the upper portion of FIG. 3. The elements identified for entry load lock 2 do not have a prime symbol for the respective numerals. However, corresponding elements in the exit load lock logic, which is provided in the lower portion of FIG. 3, have been identified by the same numerals but with a prime designation to illustrate correspondence with like elements for the entry load lock 2.

As illustrated in FIG. 3, pressure differential ΔP which is the desired pressure at which a control signal is to be developed for controlling the evacuation threshold levels for large and small evacuation valves 9 and 10 for entry load lock 2 is input on line 35. The actual change in pressure in the main processing chamber 1, as measured by the pressure gauge 8 when flap valve 5 opens and then closes (i.e., measured ΔP) is entered on entry line 33. This measured ΔP is then filtered by filter 37 using an input filter factor 39 which can be entered by an operator. The filter 37 operates to filter actual pressure measurements over a number of prior cycles of the opening and closing of flap valve 5 to filter out aberrations in any one given cycle. The filter 37 can assign weight to measured ΔP's for one or more prior cycles in performing its filtering function. The filter factor 39 sets the weight of the filtered value in the previous cycle to the measured ΔP in the current cycle in calculating the new filtered value for the current cycle cycles. This provides a cumulative moving average to filter out anomalies.

As illustrated in FIG. 3, a filter factor of 2 has been set for filter 37, meaning that the previous filtered value will be integrated with the new calculated value at a ratio of 2:1; that is, two parts previous filtered total to one part current new calculated value. The output of filter 37 is then compared with (subtracted from) the set pressure difference on input 35, and a difference signal is provided to a gain stage 45 in which a system gain can be set by an operator input at 47. The output of the gain stage 45 then goes into a limit alarm stage 49.

The limit alarm stage 49 ensures that a signal produced by gain stage 45 will not exceed a desired limit on a change in the setting of the evacuation pressure thresholds for valves 9 and 10 for a cycle. That limit is set by operator input at input 51. An alarm indicator can be activated if the limit on change is exceeded. The output of the limit stage 49, which represents the amount of change to be applied to evacuation values 9 and 10 and which is displayed to an operator, is sent to a frequency adjustment stage 54 which operates like a counter. The adjustment stage 54 will only allow the output of the limit alarm circuit 49 to pass after a certain number of substrate 19 entry cycles have been recorded. A frequency adjustment stage value is set at operator input 56. Likewise, the remaining cycles before an output of the adjustment stage 54 can cause a change in the evacuation pressure thresholds for values 9 and 10 is set at 56. The remaining number of cycles until the next permitted adjustment is illustrated at a display 58.

The output of the frequency adjustment circuit 54 is added to a feedback signal from a minimum alarm stage 57. Specifically, the output signal of stage 57 controls both the evacuation pressure thresholds for valves 9 and 10. Specifically, the minimum alarm stage 57 sets a lower limit on an evacuation pressure threshold which can be set for valves 9 and 10. Operator input to the minimum alarm stage 57 is illustrated as 61. The output of the minimum alarm stage 57 is then used to set the evacuation pressure threshold for the large evacuation pump 9. An add stage 63 is used to provide a fixed offset from the evacuation pressure threshold value for large valve 9 as the value for evacuation pressure threshold for smaller valve 10. This offset threshold can be set by an operator at an input 65. The evacuation thresholds at which the large and small evacuation valves 9 and 10 close are illustrated on display 67, 69 and are also applied as respective signals to the valves 9 and 10.

As noted earlier, the logic control system for the exit load lock 3 is constructed and operated in similar fashion and a detailed description is not repeated again herein. Suffice it to say that the prime elements of the exit load lock logic control system operate in the same manner as like elements in the logic control system for the entry load lock 2 and that the pressure changes ΔP used in the logic control system for exit load lock 3 are based on openings and closings of flap valve 6.

In the logic control system embodiment illustrated in FIG. 3, the automated targeted control of a small pressure change in the main chamber 1 when flap valve 5 on the entry load lock or flap valve 6 on the exit load lock 3 are open is very effective in controlling pressure within the load locks 2 and 3 prior to the opening of flap valves 5 and 6 and thus reducing the amount of gas flow into or out of main chamber 1.

The logic control system for each of the entry and exit load locks provides an output signal Outputₙ for controlling an evacuation pressure of a load lock chamber prior to opening a communicating flap valve (5 or 6) which communicates a load lock with the main processing chamber in accordance with the following:

$${Output}_{n} = {Output}_{n - 1} + K \times filtered {error}_{n}$$

$$filtered {error}_{n} ≡ \frac{filtered {error}_{n - 1} \times f + {error}_{n}}{f + 1}$$

$${error}_{n} ≡ Δ {P}_{FV 2} - Δ {P}_{FV 2 Target}$$

$$K ≡ Gain$$

$$f ≡ Digital Filter Factor$$

where ΔP_{FV2} represents a detected pressure change in said main processing chamber 1 upon opening the communicating flap valve (5 or 6), ΔP_{FV2 Target} represents a target pressure change in the main processing chamber when the communicating flap valve opens and then closes, K=gain and f=a digital filter factor, and wherein ₙ₋₁ represents at least one value associated with a prior communicating valve opening and closing.

The control logic for PLC 32, which is part of the overall control system, further includes provisions to prevent the near simultaneous operation of flap valve 5 and flap valve 6. The entry 2 and exit 3 load locks typically operate asynchronously thus near simultaneous operation is possible. Such near simultaneous operation would confound the ΔP input measurements to both the entry and exit control systems and thus must be prevented. The exit load lock 3 must begin its cycle once glass substrate 19 is present upstream from flap valve 6, so alteration of flap valve 6 operation logic within PLC 32 is prohibited. Thus additional control logic is used within PLC 32 to delay the opening of flap valve 5 such that flap valve 5 cannot open within a time window (typically ˜±3 s) around the flap valve 6 open event. If the PLC 32 detects a near simultaneous event, it notifies PLC 31 so that control logic of PLC 31 inhibits the update of ΔP valves due to the uncertainty of the ΔP interpretation.

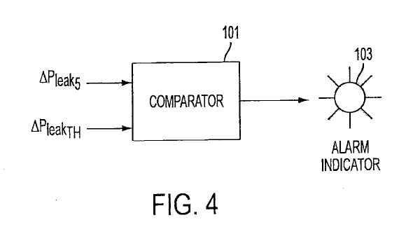

Detected pressure differences in the main processing chamber 1, as sensed by pressure gauge 8, can also be used to determine if there are leaks across either of the flap valves 5, 6. For this operation, the main chamber 1 pressure is measured before and after the load locks 2, 3 are vented by respective vent valves 20 and 21. For entry load lock 2 vent valve 20 vents the interior of load lock 2 to atmosphere or with another gas such as N2 prior to the opening of flap valve 4, while for exit load lock 3 venting occurs by pressurizing the interior of the exit load lock 3 with N2 through valve 21 prior to the opening of flap valve 7. A pressure difference within main chamber 1 before and after venting by each of vent valves 20 and 21 can be used to detect leaks across flap valves 5, 6 respectively as respective differential leak pressures ΔPₗₑₐₖ₅ and ΔPₗₑₐₖ₆. If the values ΔPₗₑₐₖ₅ and ΔPₗₑₐₖ₆ show a step up in main chamber pressure caused by the operation of either valve 20 or valve 21, a leak across the respective flap valve 5 or 6 is indicated. As shown in FIG. 4, differential pressure values ΔPₗₑₐₖ₅ and ΔPₗₑₐₖ₆ may be used as inputs to a respective comparator 101 which can set an alarm condition when the ΔPₗₑₐₖ₅ or ΔPₗₑₐₖ₆ valves exceed predetermined thresholds. The comparator 101 may be a simple threshold detector and alarm indictor 103 as shown in FIG. 4, which depicts the leak detection control system for entry load lock 2 in which case ΔPₗₑₐₖ₅ is used as an input. An identical leak detection control system is used for exit load lock 3, except ΔPₗₑₐₖ₆ would be the input to comparator 101. Comparator 101 may be incorporated as part of the overall control system for operating the FIG. 1 system and may be included within PLC 31 shown in FIG. 2.

While embodiments have been described and illustrated, it should be understood that many modifications and changes can be made to these embodiments without departing from the spirit or scope of the invention. Accordingly, the invention is not limited by any description contained herein, but is only limited by the scope of the appended claims.

What is claimed as new and desired to be protected by Letters Patent of the United States is:

1. A processing apparatus comprising:
a processing chamber having a pressure sensor for sensing pressure in said processing chamber;
at least one other chamber connected to said processing chamber, said other chamber including a first valve which opens and closes for selectively allowing a first object to pass between said other processing chamber and said other chamber; and
a control system for controlling pressure in said other chamber prior to opening of said first valve, said control system being responsive to a detected pressure change in said processing chamber by said pressure sensor caused by at least one prior opening and closing of said first valve.

2. A processing apparatus as in claim 1, wherein said at least one other chamber is a load lock chamber and said first valve is a first flap valve.

3. A processing apparatus as in claim 2, further comprising a conveying mechanism for moving said first object through said first valve.

4. A processing apparatus as in claim 1, wherein said control system is responsive to a detected pressure change in said processing chamber caused by at least a second object entering into or passing from said processing chamber ahead of said first object.

5. A processing apparatus in claim 4, wherein said control system is responsive to a plurality of detected pressure changes in said chamber caused by a plurality of second objects sequentially passing between said chamber and said other chamber through said first valve before the passing of said first object between said processing chamber and said other 1 chamber.

6. A processing apparatus as in claim 2, wherein said control system controls at least one evacuation pressure valve for evacuating said load lock chamber through said at least one evacuation valve.

7. A processing apparatus as in claim 6, wherein said control system controls two evacuation pressure values for evacuating said load lock chamber through said two evacuation valves.

8. A processing apparatus as in claim 7, wherein one of said two evacuation values provides a larger evacuation flow rate than a second of said two evacuation values.

9. A processing apparatus as in claim 6, wherein said control system controls said at least one evacuation valve to close when a predetermined evacuation pressure threshold is reached in said load lock chamber.

10. A processing apparatus as in claim 8, wherein said control system controls said two evacuation values to close when respective predetermined evacuation pressure thresholds are reached in said load lock chamber.

11. A processing apparatus as in claim 10, wherein said respective predetermined evacuation thresholds are offset from one another.

12. A processing apparatus as in claim 11, wherein said control system receives as an input an amount of said offset.

13. A processing apparatus as in claim 2, wherein said control system receives as an input a set pressure change in said processing chamber which said control system uses with said detected pressure change to control evacuation pressure in said load lock chamber.

14. A processing apparatus as in claim 2, wherein said control system includes a signal filter for controlling evacuation pressure in said load lock chamber in response to pressure changes in said main chamber associated with a plurality of prior openings and closings of said first flap value.

15. A processing apparatus as in claim 2, wherein said control system includes an alarm indicator when a signal used to control evacuation pressure in said load lock chamber is outside set limits.

16. A processing apparatus as in claim 2, wherein said control system sets a limit on an adjustment of an evacuation pressure in said load lock chamber which can be made.

17. A processing apparatus as in claim 2, wherein said control system includes an alarm indication when a signal used to control pressure in said load lock chamber is below a set pressure limit.

18. A processing apparatus as in claim 2, wherein said load lock chamber is located at an entry to said processing chamber and passes said first object into said processing chamber.

19. A processing apparatus as in claim 2, wherein said load lock chamber is located at an exit of said processing chamber and receives said first object from said processing chamber.

20. A processing apparatus as in claim 2, further comprising two load lock chambers, one located at an entry to said processing chamber for passing said first object into said processing chamber and one located at an exit of said processing chamber, for receiving a processed first object from said processing chamber, each of said load lock chambers having a respective first flap valve, said control system separately controlling an evacuation pressure in each of said load lock chambers.

21. A processing apparatus as in claim 3, wherein said conveying mechanism conveys successive objects through said processing chamber and load lock chamber, and said control system produces control signals which periodically reset a desired evacuation pressure in said load lock chamber based on detected pressure changes in said processing chamber after a predetermined number of objects pass between said load lock chamber and said processing chamber.

22. A processing apparatus as in claim 2, wherein said processing chamber is a vapor transport deposition coater chamber.

23. A processing apparatus as in claim 19, wherein said control system controls respective first flap in said entry and exit load lock chambers to prevent said respective first flap valves from opening at the same time.

24. A processing apparatus as in claim 2, wherein said control system provides a control output signal Outputₙ for controlling an evacuation pressure of said load lock chamber prior to said first valve opening, where ΔP_{FV2} represents a detected pressure change in said processing chamber upon said first flap valve opening and ΔP_{FV2 Target} represents a target pressure change in said processing chamber when the first flap valve opens and closes, and where
$${Output}_{n} = {Output}_{n - 1} + K \times filtered {error}_{n}$$
$$filtered {error}_{n} ≡ \frac{filtered {error}_{n - 1} \times f + {error}_{n}}{f + 1}$$
$${error}_{n} ≡ Δ {P}_{FV 2} - Δ {P}_{FV 2 Target}$$
$$K ≡ Gain$$
$$f ≡ Digital Filter Factor$$
and where ₙ₋₁ represents at least one value associated with a prior first valve opening and closing.

25. A processing apparatus as in claim 2, wherein said control system is operable to determine a leak condition across said first flap valve in response to said pressure sensor sensing pressure changes in said processing chamber caused by a venting of said load lock chamber.

26. A processing apparatus as in claim 25, wherein said control system compares a sensed pressure difference before and after said venting with a threshold value and provides an alarm indication when said threshold value is exceeded.

27. A method of process control comprising:
successively conveying a plurality of objects into a vapor deposition chamber having at least one openable and closeable load lock through which said objects pass which is located at least at one of an entry to and exit from said chamber; and
controlling the evacuation pressure within said at least one load lock to a determined value prior to said at least one load lock opening to communicate with said vapor deposition chamber in accordance with one or more detected pressure changes in said vapor deposition chamber caused by one or more respective prior openings of said load lock.

28. A method as in claim 27, wherein said at least one load lock is located at an entry to said deposition chamber.

29. A method as in claim 27, wherein said at least one load lock is located at an exit of said deposition chamber.

30. A method as in claim 27, wherein said at least one load lock comprises an entry load lock located at an entry to said chamber and an exit load lock located at an exit of said chamber, and the evacuation pressure within each load lock is separately controlled in accordance with respective detected pressure changes in said chamber caused by one or more prior openings and closings of a respective load lock.

31. A method as in claim 28, wherein said load lock has non-simultaneously operating first and second flap valves to respectively allow an object to enter into said load lock and exit from said load lock into said deposition chamber, said method further comprising:
venting said load lock;
opening said first flap valve, conveying an object into said load lock, and then closing said first flap valve;
evacuating said load lock to said predetermined evacuation pressure value while said first and second flap valves are closed; and
opening said second flap valve, conveying said object into said deposition chamber, and then closing said second flap valve.

32. A method as in claim 29, wherein said load lock has non-simultaneous operating first and second flap valves to respectively allow an object to enter into said load lock from said deposition chamber, said method further comprising:
evacuating said load lock to said predetermined evacuation pressure while said first and second flap valves are closed;
opening said first flap valve, conveying an object into said load lock from said deposition chamber, and then closing said load lock;
venting said load lock; and
opening said second flap valve, conveying said object out of said load lock, and then closing said second flap valve.

33. A method as in claim 30, further comprising preventing the simultaneous communication of an interior a chamber of said entry and exit load locks with said vapor deposition chamber.

34. A method as in claim 27, wherein said at least one prior opening of said load lock includes an immediately preceding opening of said load lock.

35. A method as in claim 27, wherein said at least one prior opening of said load lock includes a plurality of preceding openings of said load lock.

36. A method as in claim 35, wherein at least one of said plurality of preceding openings of said load lock is an immediately preceding opening of said load lock.

37. A method as in claim 27, wherein controlling said evacuation pressure comprises:
detecting a pressure change in said deposition chamber caused by at least one prior opening of said load lock;
comparing a set pressure change with a detected pressure change to generate a control signal; and
using said control signal to establish a desired evacuation pressure in said load lock prior to an opening of said load lock which establishes communication between said load lock and deposition chamber.

38. A method as in claim 37, wherein said control signal controls evacuation pressure at which at least one evacuation valve used in evacuating said load lock closes.

39. A method as in claim 38, wherein said control signal controls respective evacuation pressures at which a first and second evacuation valves used in evacuating said load lock close, with one of said first and second evacuation valves having a higher evacuation flow rate than the other.

40. A method as in claim 27, wherein said evacuation pressure is controlled in accordance with an output signal Outputₙ prior to an opening ₙ of said load lock where ΔP_{FV2} represents a detected pressure change in said deposition chamber and ΔP_{FV2 Target} represents a target pressure change in said deposition chamber where
$${Output}_{n} = {Output}_{n - 1} + K \times filtered {error}_{n}$$
$$filtered {error}_{n} ≡ \frac{filtered {error}_{n - 1} \times f + {error}_{n}}{f + 1}$$
$${error}_{n} ≡ Δ {P}_{FV 2} - Δ {P}_{FV 2 Target}$$
$$K ≡ Gain$$
$$f ≡ Digital Filter Factor$$
and where ₙ₋₁ represents values associated with a prior opening of said load lock.

41. A method as in claim 27, further comprising determining a leak condition between said vapor deposition chamber and said load lock, when said load lock is closed, by sensing detected pressure changes in said vapor deposition chamber before and after said load lock is vented.

42. A method as in claim 27, wherein said controlling the evacuation pressure sets a limit on the amount of control which can be exerted when controlling said evacuation pressure.

43. A method as in claim 27, further comprising controlling said evacuation pressure in accordance with a control system which receives as inputs a set pressure change in said deposition chamber and an actual detected pressure change detected in said deposition chamber caused by at least one prior opening and closing of said load lock.

44. A method as in claim 43, wherein said control system filters a plurality of prior pressure changes in said deposition chamber and uses said filtered pressure changes in controlling said evacuation pressure.

45. A method as in claim 43, wherein said control system has a settable gain setting.

46. A method as in claim 43, wherein said control system includes a settable limit on how much change can be made in a signal which controls said evacuation pressure.

47. A method as in claim 43, wherein said control system includes a settable number of openings of said load lock before a change of setting for controlling said evacuation pressure is made.

48. A method as in claim 43, wherein said control system has a settable limit on a signal developed by said control system which controls said evacuation pressure.

49. An apparatus comprising:
a vapor deposition chamber for depositing material on an object;
a load lock located at least at one of an entry and exit of said deposition chamber, said load lock comprising an interior chamber and an openable and closable flap valve for permitting said object to pass between said deposition chamber and said interior chamber of said load lock;
a vent valve for venting said interior chamber of said load lock;
a pressure sensor for sensing pressure within said deposition chamber before and after said interior chamber is vented by said vent valve; and
a system for determining a differential pressure of said deposition chamber before and after said interior chamber is vented and providing an indication when said differential pressure exceeds a threshold value.

50. An apparatus as in claim 49, wherein said load lock is on an entry side of said deposition chamber.

51. An apparatus as in claim 50, wherein said load lock is on an exit side of said deposition chamber.

52. An apparatus as in claim 49, wherein said indication indicates a leak across said flap valve.

53. A method comprising:
detecting the pressure in a vapor deposition chamber before and after the interior chamber of a load lock located at least at one of an entry and exit of said deposition chamber is vented; and
determining if there is a leak present across a flap valve separating an interior or said load lock from said vapor deposition chamber using a pressure differential developed from said detected pressure.

54. A method as in claim 53, wherein said load lock is located at an entry to said vapor deposition chamber.

55. A method as in claim 53, wherein said load lock is located at an exit of said vapor deposition chamber.

56. A method as in claim 53, wherein said differential pressure is compared with a threshold pressure to determine if a leak is present.
